(19) United States
(12) Patent Application Publication
(10) Pub. No.: US 2019/0051565 A1
(43) Pub. Date: Feb. 14, 2019

(54) CMOS DEVICES AND MANUFACTURING METHOD THEREOF

(71) Applicant: GLOBALFOUNDRIES Inc., Grand Cayman (KY)

(72) Inventors: Peter Baars, Dresden (DE); Hans-Juergen Thees, Dresden (DE); Thorsten Kammler, Dresden (DE)

(21) Appl. No.: 15/673,519

(22) Filed: Aug. 10, 2017

(51) Int. Cl. H01L 21/8238; H01L 27/092; H01L 21/8234

(52) U.S. Cl. CPC H01L 21/823807; H01L 21/823842; H01L 27/0925; H01L 2027/11822; H01L 21/823418; H01L 27/092; H01L 21/823857

(57) ABSTRACT

A method of manufacturing a complementary metal-oxide-semiconductor (CMOS) device comprising an N-type metal-oxide-semiconductor (NMOS) region and a P-type metal-oxide-semiconductor (PMOS) region is provided, that comprises: depositing a raised source and drain (RSD) layer of a first type in the NMOS region and the PMOS region at the same time; selectively removing the RSD layer of the first type in one of the NMOS region and the PMOS region; and depositing an RSD layer of a second type in the one of the NMOS region and the PMOS region.

### BACKGROUND

### 1. Field of the Disclosure

Generally, the subject matter disclosed herein relates to integrated circuits and particularly to transistor devices, in particular, field effect transistor devices with raised source and drain regions.

### 2. Description of the Related Art

As integrated circuits become more and more integrated, the sizes of the corresponding circuit elements, such as transistors, have to shrink accordingly. As a consequence, field effect transistors (FETs) with very thin gate dielectric layers using a high-k dielectric have been developed to mitigate short channel effects. Unfortunately, very thin gate insulators have resulted in increased gate leakages or gate-induced leakages increasing circuit stand-by power for short transistor gate lengths. As a remedy, sub-threshold leakage and other short channel effects have been controlled and reduced by thinning the device channel layer.

Fully depleted (FD) devices have been formed in ultrathin silicon-on-insulator (SOI) layers, for example, where the silicon channel layer is less than 50 nm or, in some cases, less than 10 nm thick. Ultrathin FDSOI devices operate at lower effective voltage fields. Furthermore, ultrathin FDSOI devices have a steeper sub-threshold current swing with current falling off sharply as the gate-to-source voltage drops below the threshold voltage.

In FDSOI devices, an ultrathin oxide insulator is placed on top of the base silicon. Second, a very thin silicon layer creates the transistor channel. Due to the very low thickness of this channel layer, no channel doping is required, making the transistor fully depleted. The buried insulation (e.g., oxide) layer also constrains electrons flowing between the source and drain to significantly reduce performance and power-degrading leakage current. The fully depleted channel also reduces leakage.

As forming the source/drain region from the same ultrathin silicon layer increases external resistance and, in particular, contact resistance, raised source/drain (RSD) regions have to be formed. The thicker silicon RSD regions have a larger cross-sectional area for lower resistance per unit area (sheet resistance) and are heavily doped, such that they are effective in overcoming the external resistance problem. However, RSD regions that are positioned close to the gate conductor edge will increase the capacitance between the gate and the source/drain regions. Thus, while RSD structures are often utilized, particularly for ultrathin MOSFETs and for FDSOI FETs, to reduce series or parasitic resistance or junction leakage, they generally lead to an increased capacitance, e.g., increased parasitic capacitance. As a result, much effort has been dedicated to the formation of sidewall spacers with optimal thickness and materials. Meanwhile, low-k spacer materials are used to reduce the parasitic capacitance.

In complementary metal-oxide-semiconductor (CMOS) devices comprising an N-type metal-oxide-semiconductor (NMOS) transistor and a P-type metal-oxide-semiconductor (PMOS) transistor, it has proven difficult in the past to manufacture sidewall spacers for the gate structures of the NMOS or NFET transistor and the PMOS or PFET transistor of comparable thickness. As a result of the different dopant types, i.e., N-type dopants, like phosphorus, and P-type dopants, like boron, of the raised source and drain regions of the NFET and PFET transistors, the NMOS and PMOS regions of CMOS devices are processed independently in the art, using dual epitaxial growth of the corresponding layers and separate etch steps for the formation of the respective sidewall spacers. The subsequent processing of the NMOS and PMOS regions leads to different thicknesses of the sidewall spacers of the NFET and PFET transistors. Manufacturing NFET and PFET transistors of CMOS devices with comparable parasitic capacitance, therefore, involves complicated manufacturing processes.

In the currently developed 12 nm FDSOI technology, the differences in the thickness of the sidewall spacers of the NFET and PFET transistors generally lie in the range of 2 nm or more. Also, the manufacturing processes cannot simply be modified to allow for engineering of source and drain extensions. In particular, a differential spacer approach which uses a sacrificial spacer cannot be applied to the 12 nm FDSOI technology due to the tighter SRAM pitch (spacer bridging) and the need for junction engineering. Also, a differential spacer approach requires additional masks, thereby further adding to the complexity of the manufacturing process.

In view of the above, it is desirable to provide an improved manufacturing method for CMOS devices with sidewall spacers of the NFET and PFET transistors of substantially identical thickness, i.e., a deviation between the thicknesses of the sidewall spacers of the NFET and PFET transistors of less than 2 nm. In particular, a simplification of the complex manufacturing methods known in the art is desirable.

### SUMMARY OF THE DISCLOSURE

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally the subject matter disclosed herein relates to field effect transistor (FET) devices, in particular CMOS devices with an NFET transistor and a PFET transistor, and methods for fabricating the same, wherein sidewall spacers of the NFET and the PFET transistors with substantially identical thickness are formed. Therefore, the disclosed method solves the problem of different spacer thicknesses resulting from the two different RSD epitaxy steps required by the methods known in the art.

The formation of sidewall spacers with substantially identical thickness on the NFET and PFET transistors is achieved by etching a conformally deposited spacer layer in the NFET and PFET regions of the CMOS device at the same time, i.e., without a mask covering either the NFET or the PFET region. As a result, only one etch step is required to form the sidewall spacers in the simplest form of the manufacturing process.

If the formation of source and drain extensions is desired, inner sidewall spacers of substantially identical thickness may be formed as described above in a single etch step. Subsequently, source and drain extensions may be formed using the gate stacks and the inner sidewall spacers as a mask and performing plasma-assisted doping or shallow implantation with respective impurities.

Formation of the sidewall spacers may then be completed by conformally depositing an outer spacer layer and anisotropic etching of the deposited layer in both the NFET and PFET regions at the same time to form outer sidewall spacers.

The present disclosure also provides a simplification of the process of reference for forming raised source and drain regions in the NFET and PFET regions of a CMOS device while keeping the dual epitaxial growth approach. Consequently, the raised source and drain regions of the NFET and PFET transistors are still formed by two epitaxy steps which grow correspondingly doped semiconductor layers on the SOI substrate.

Different from the process of reference, however, the first epitaxy step is performed in both the NFET and PFET regions such that the epitaxial layer is grown in both regions. The part of the epitaxial layer grown in the region with the opposite polarity, i.e., the opposite dopant type, for instance the part of a P-type epitaxial layer in the NFET region, is provided as a sacrificial layer. The manufacturing methods according to the present disclosure make use of the selectivity of an etch step with respect to the substrate when removing this sacrificial layer. Once the sacrificial layer is removed, the second epitaxy step is performed to grow raised source and drain regions of the appropriate polarity, i.e., n-type-dopant, in the NFET region.

Separation of the formation of the sidewall spacers of the NFET and PFET transistors from the formation of the raised source and drain regions not only provides sidewall spacers of substantially identical thickness, but also reduces the number of masks required in the manufacturing process, and thereby simplifies the manufacturing process.

The simultaneous etch of the spacer layer with subsequent deposition of a sacrificial layer is compatible with both the formation of source and drain extensions and the formation of thick input/output spacers as they are required for I/O devices. As the sidewall spacers of the NFET and PFET transistors are etched at the same time, no additional steps with respect to the process of reference are needed for the formation of source and drain extensions. Rather, fewer masks are required, which makes the manufacturing process more economic.

A single spacer layer may be used for both, the formation of the sidewall spacers of the NFET and PFET transistors of the CMOS device and the formation of thick, L-shaped sidewall spacers of the I/O device. Also, epitaxial growth of the raised source and drain regions of the CMOS device may be conveniently combined with the epitaxial growth of the raised source and drain regions of the I/O device. The manufacturing process of NFET and PFET transistors with substantially identical sidewall spacer thickness may, thus, be easily combined with manufacturing methods known in the art, such as source and drain extensions, junction engineering and thick sidewall spacers.

The described structures and methods provide CMOS devices with homogeneous sidewall spacers and, thus, reduced parasitic capacitance.

### BRIEF DESCRIPTION OF THE DRAWINGS

The disclosure may be understood by reference to the following description taken in conjunction with the accompanying drawings, in which like reference numerals identify like elements, and in which:

FIGS. 1A-H illustrate an exemplary manufacturing process of a CMOS device with spacers of substantially identical thickness for NFET and PFET transistors using a sacrificial epitaxial layer, according to the present disclosure;

FIGS. 2A-E illustrate a variant of the exemplary manufacturing process according to FIGS. 1A-H with the formation of extensions, according to the present disclosure; and

FIGS. 3A-E illustrate a further variant of the exemplary manufacturing process according to FIGS. 1A-H with the formation of thick I/O spacers, according to the present disclosure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The following embodiments are described in sufficient detail to enable those skilled in the art to make use of the invention. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it would be apparent that the embodiments of the disclosure may be practiced without the specific details. In order to avoid obscuring the present disclosure, some well-known circuits, system configurations, structure configurations and process steps are not disclosed in detail.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As used herein, directional terms such as “over,” “on,” “underneath,” “above,” “below,” “upper,” “lower,” “vertical” and “horizontal” are intended to provide relative positions for purposes of the description, and are not intended to designate an absolute frame of reference. For example, FETs may be oriented spatially in any manner different from the orientations shown in the drawings. “Vertical” is used to refer to a direction normal to the surface of the substrate, “horizontal” is used to refer to a direction parallel to the surface of the substrate, and “planar” is used to refer to the plane parallel to the surface of the substrate. “Upper” is used to refer to a vertical direction away from the surface of the substrate. An element positioned “above” (“below”) another element is located farther away from (closer to) the surface of the substrate as compared to the other element. The term “on” is used to indicate that there is direct contact between elements.

As will be readily appreciated by those skilled in the art upon a complete reading of the present application, the present disclosure is applicable to a variety of technologies, in particular to CMOS devices, and is readily applicable to a variety of devices, including, but not limited to, logic devices, memory devices, SRAM devices etc., in principle. Although the term “MOS” properly refers to a device having a metal gate electrode and an oxide gate insulator, that term is used throughout to refer to any semiconductor device that includes a conductive gate electrode (whether metal or other conductive material) that is positioned over a gate insulator (whether oxide or other insulator) which, in turn, is positioned over a semiconductor bulk substrate.

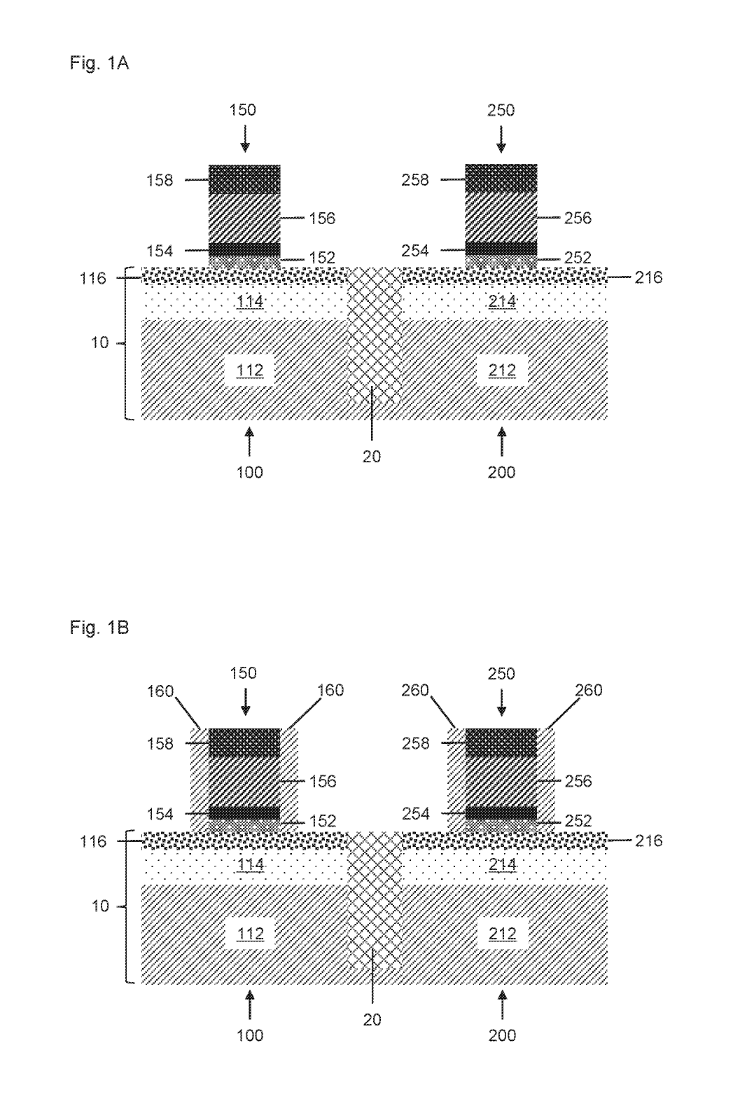

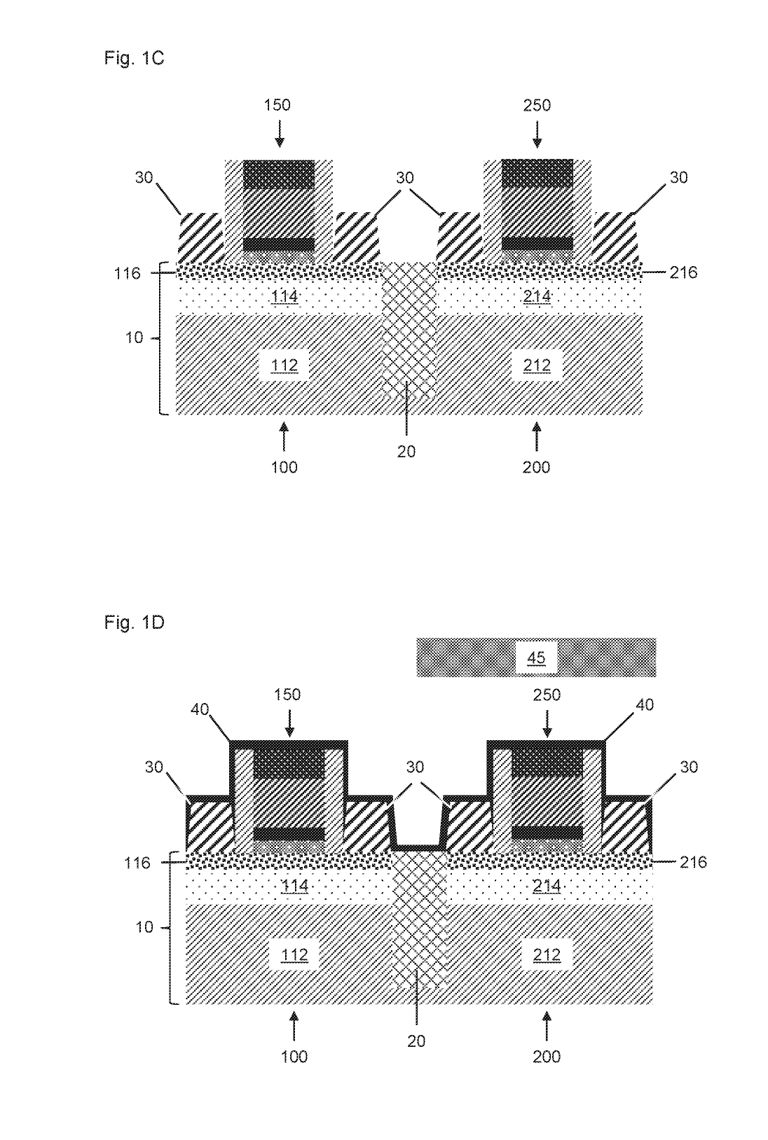

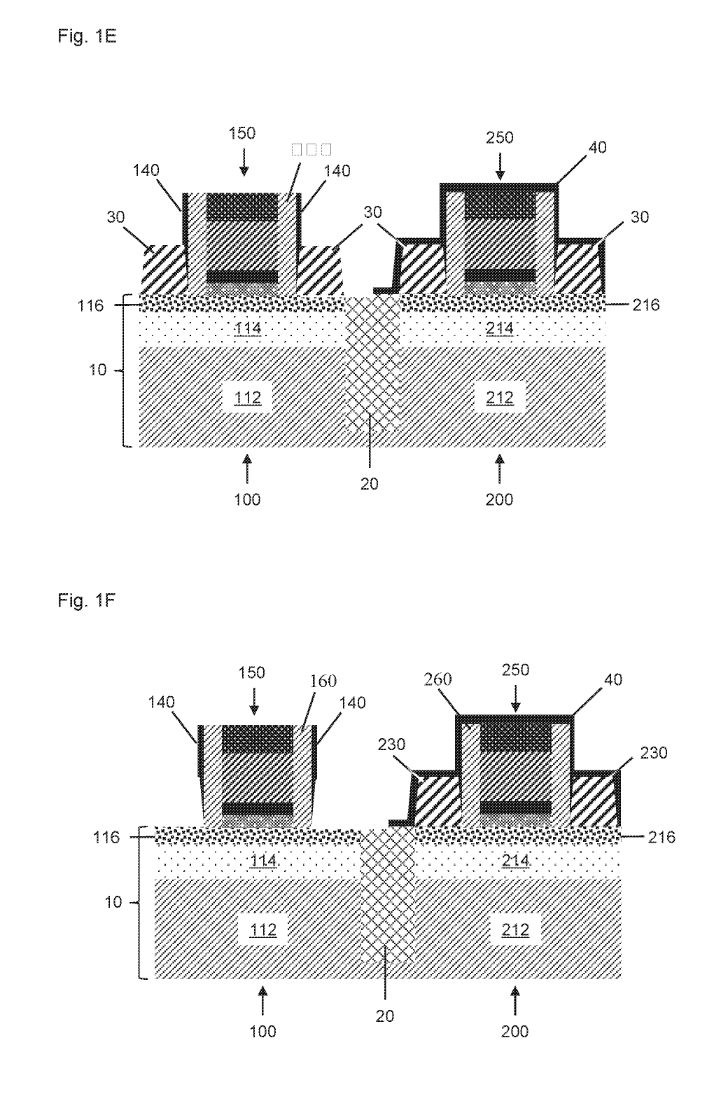

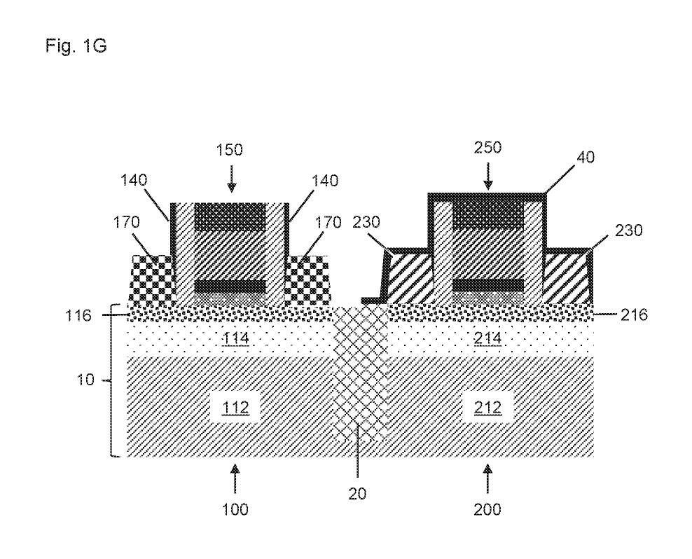

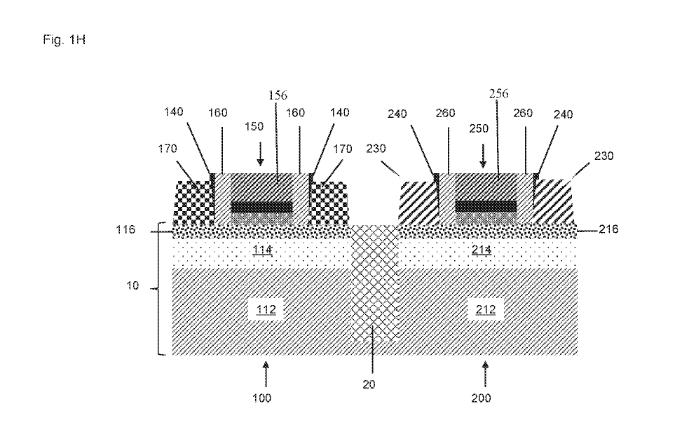

FIG. 1A shows a cross-section of a CMOS device after patterning of multilayer stacks for high-k metal gates (HKMG) for an NFET transistor 100 and a PFET transistor 200. For the sake of brevity, not every manufacturing step is illustrated individually such that multiple manufacturing steps may be summarized. In particular, well-known manufacturing techniques are neither illustrated nor described in detail to avoid obscuring the present disclosure. It shall nevertheless be understood that such manufacturing techniques may be applied to form the described structure, and variations to the described manufacturing techniques known in the art are also included in the present disclosure.

The illustrative examples shown in the present disclosure show single gate devices. However, it shall be understood that the present disclosure can also be applied to devices with two or more gates. In the illustrative example of FIG. 1A, multilayer stacks 150 and 250 for two HKMG gates are provided on a substrate 10. The term “substrate” as used herein is intended to include a semiconductor substrate, a semiconductor epitaxial layer deposited or otherwise formed on a semiconductor substrate and/or any other type of semiconductor body. For example, the semiconductor substrate may comprise a semiconductor wafer (e.g., silicon, SiGe, or an SOI (Semiconductor-On-Insulator) wafer) or one or more die on a wafer, and any epitaxial layers or other type of semiconductor layers formed there above.

According to the illustrative example shown in FIG. 1A, two multilayer stacks are provided on an SOI substrate 10, in particular an FDSOI substrate. The SOI substrate 10 comprises a semiconductor bulk substrate 112, 212, a buried insulation (e.g., oxide) layer (BOX) 114, 214 formed on the semiconductor bulk substrate 112, 212, and a semiconductor layer 116, 216 formed on the BOX layer 114, 214. Although formed from continuous layers, the semiconductor bulk substrates 112, 212, and likewise the BOX layers 114, 214 as well as the semiconductor layers 116, 216, are identified by separate reference signs to refer to the respective elements of the NMOS or NFET region 100 and the PMOS or PFET region 200, respectively, of the CMOS device. The same applies to the elements of the gate stacks 150 and 250 of the NFET region 100 and the PFET region 200.

The semiconductor layer 116, 216 may comprise a significant amount of silicon due to the fact that semiconductor devices of high integration density may be formed in volume production on the basis of silicon due to the enhanced availability and the well-established process techniques developed over the last decades. However, any other appropriate semiconductor materials may be used, for instance, a silicon-based material containing other iso-electronic components, such as germanium, carbon, silicon/germanium, silicon/carbon, other II-VI or III-V semiconductor compounds and the like.

The NFET 100 may be formed with a non-strained Si channel, while the PFET 200 may be formed with a strained SiGe channel, according to known processing techniques for the manufacturing of best performing FDSOI CMOS devices. The present disclosure is, however, not limited to such devices but may be applied to any kind of channel structure.

The BOX layer 114, 214 may comprise silicon (di)oxide or a borosilicate glass (BPSG). The BOX layer 114, 214 may be composed of different layers and one of the different layers may comprise BPSG or an SiO₂-compound comprising boron or phosphorus. The semiconductor bulk substrate 112, 212 may comprise or consist of silicon, in particular, single crystal silicon. Other materials can be used to form the semiconductor bulk substrate 112, 212 such as, for example, germanium, silicon germanium, gallium phosphate, gallium arsenide, etc. By way of example, the thickness of the semiconductor layer 116, 216 may be in the range of 5-30 nm, in particular 5-10 nm, and the thickness of the BOX layer 114, 214 may be in the range of 10-50 nm, in particular 10-30 nm, more particularly 15-25 nm. The substrate 10 may further be a lightly doped P-type substrate.

The semiconductor substrate 10 may contain active device regions, such as the NFET region 100 and the PFET region 200, wiring regions, isolation regions or other like regions that are typically present in CMOS-containing devices. For clarity, only the NFET region 100 and the PFET region 200 are included in the illustrative example shown in FIG. 1A.

Shallow trench isolation (STI) regions 20 may be formed in the SOI substrate 10 to electrically isolate the NFET transistor 100 from the PFET transistor 200 and/or other electric components of an integrated circuit (IC) formed on the SOI substrate. The STI regions 20 may be formed by etching openings through the semiconductor layer 116, 216 and the BOX layer 114, 214 and into the semiconductor bulk substrate 112, 212 and then filling the openings with an insulating material, such as a silicon oxide material.

The multilayer stacks 150 and 250 for the HKMG gates include an HKMG layer 154, 254 over the semiconductor layer 116, 216, respectively, a gate electrode layer 156, 256 on the HKMG layer 154, 254, and a hard mask layer 158, 258 on the gate electrode layer 156, 256. An SiO₂ interface layer 152, 252 may be provided between the semiconductor layer 116, 216 and the HKMG layer 152, 252, respectively. The SiO₂ layer 152, 252 may, thus, be provided as a gate insulating layer on the semiconductor layer 116, 216, respectively. Furthermore, an La-based cap (not shown) may be provided on the HKMG layer 154 and under the gate electrode layer 156 of the NFET. Also, an Al₂O₃ cap (not shown) may be provided on the HKMG layer 254 and under the gate electrode layer 256 of the PFET 200.

The HKMG layer 154, 254 may comprise a bottom layer comprising or consisting of a high-k dielectric material, i.e., a material with a dielectric constant k greater than about 3.9, such as hafnium-oxide (HfO₂), hafnium-silicon-oxide (HfSiO₃) or hafnium-lanthanum-oxide (HfLaOₓ). Other metal oxide-based materials may be used as well, such as a uniform or composite layer comprised of one or more of Ta₂O₅, TiO₂, Al₂O₃, Y₂O₃ and La₂O₅. According to some examples, the high-k dielectric layer may be formed directly on the semiconductor layer 116, 216. According to other examples, the high-k dielectric layer may be formed on an insulating layer 152, 252, respectively, comprising silicon oxide or silicon oxynitride, which is formed on the semiconductor layer 116, 216. The high-k dielectric layer 154, 254 may have a thickness in a range of about 1-3 nm. The insulating layer 152, 252 may be formed by dry or rapid thermal oxidation by exposing the semiconductor layer 116, 216 to an oxidizing ambient. The HKMG layer 154, 254 may be formed by various methods of chemical vapor deposition (like RT-CVD) or atomic layer deposition (ALD).

The HKMG layer 154, 254 may further comprise a work function metal layer, such as TiN, as a middle layer or as part of a middle layer on the gate dielectric layer. Any other appropriate work function adjusting metal or metal oxide that is known in the art may be used for the work function metal layer. The work function metal layer may be considered as the metal-containing layer of a metal gate and may have a thickness as low as about 10 nm. A further metal-containing layer comprising at least one of tantalum nitride (TaN), tantalum (Ta), tungsten (W) or the like with a thickness below 50 nm, in particular below 20 nm, may be provided on the work function metal layer as part of the gate electrode layer 156, 256. Despite the name HKMG, such an additional metal-containing layer is not required for the gate electrode due to the presence of the work function metal layer. For the sake of clarity, this metal-containing layer is not shown explicitly in the figures. Nevertheless, it shall be understood that the above-described examples of the HKMG layer may be used in the present and all other figures of the present disclosure.

The multilayer stacks 150, 250 comprise a gate electrode layer 156, 256 on the HKMG layer 154, 254, respectively. The gate electrode layer 156, 256 may be an amorphous or polycrystalline silicon layer with a thickness in a range of about 15-100 nm, more specifically in the range of about 20-30 nm. The silicon gate electrode layer 156, 256 may be doped with impurities of the appropriate type and density to provide the desired conductivity, for instance by in situ doping or ion implantation. The gate electrode layer may be formed using known techniques such as CVD or ALD. The possible dopants include, but are not limited to, As, B and P.

Finally, a hard mask layer 158, 258 is deposited on the gate electrode layer 156, 256 as part of the initial multilayer stack. The hard mask layer 158, 258 may be a single SiN layer or a layer of SiO₂ on top of a SiN layer. Other appropriate materials for the hard mask layer 158, 258 may be metal, spin-on organic material, silicon carbide, tetraethyl orthosilicate (TEOS), silicon nitride carbide (SiCN), silicon oxynitride (SiON), amorphous silicon, spin-on glass (SOG) or a combination thereof. The hard mask layer 158, 258 may have a thickness in a range of 25-80 nm. The hard mask layer 158, 258 may in particular be provided as a protective layer to avoid unwanted doping of the gate electrodes during the manufacturing process.

Unless explicitly specified otherwise, “depositing” here and in the following may include any known technique appropriate for the material to be deposited, including but not limited to, for example: chemical vapor deposition (CVD), low-pressure CVD (LP-CVD), plasma-enhanced CVD (PE-CVD), semi-atmosphere CVD (SACVD) and high density plasma CVD (HDP-CVD), rapid thermal CVD (RT-CVD), ultra-high vacuum CVD (UHV-CVD), limited reaction processing CVD (LRP-CVD), metal-organic CVD (MO-CVD), sputtering deposition, ion beam deposition, electron beam deposition, laser-assisted deposition, thermal oxidation, thermal nitridation, spin-on methods, physical vapor deposition (PVD), atomic layer deposition (ALD), molecular layer deposition (MLD), chemical oxidation, molecular beam epitaxy (MBE), plating and evaporation.

Other alternative structures of the gate stacks may be used together with the present disclosure.

The layers of the gate stacks, i.e., the insulating layer 152, 252, the HKMG layer 154, 254, and the gate electrode layer 156, 256, are then patterned to form the gate stacks 150 and 250 for the control gates of the NFET transistor 100 and the PFET transistor 200. Conventional techniques such as mask and etch processes may be used. By way of example, a hard mask layer 158, 258 may be formed and patterned at the location of the gate stacks 150, 250 as shown in FIG. 1A. An anisotropic etch, such as reactive-ion-etch (RIE), may be performed to remove exposed portions of the layers of the gate stacks to pattern the two single gate stacks 150, 250.

After patterning the gate stacks 150, 250, sidewall spacers 160, 260 are formed on the sidewalls of the gate stacks 150, 250. To form the sidewall spacers 160, 260, a spacer layer (not shown), for instance including or consisting of silicon oxide, silicon nitride and/or state-of-the-art low-k materials, may be formed over the fully etched gate structures 150, 250, e.g., through a conformal deposition process such as LP-CVD or MLD. In one particular example, an SiBCN layer may be formed over the gate structures for the formation of low-k spacers for reduced capacitive coupling between the RSD regions and the gates. Also, a multilayer may be formed over the gate structures by subsequently growing or depositing respective layers. The spacer layer may then be anisotropically etched to form sidewall spacers 160 on the sides of the gate structure 150 of the NFET structure 100, and equivalently form sidewall spacers 260 on the sides of the gate structure 250 of the PFET structure 200. The resulting structure is shown in FIG. 1B.

As the deposition of the spacer layer and the subsequent etching step, for instance in the form of a blanket anisotropic spacer etch, are performed at the same time for the NFET region 100 and the PFET region 200, the sidewall spacers 160, 260 are formed with substantially identical spacer thickness. The thickness of the sidewall spacers 160, 260 may be chosen to lie in the range between 5-15 nm, in particular 8-12 nm. As a consequence of the manufacturing process of the present disclosure, the thickness of the sidewall spacers 160, 260 after the blanket etch is the final spacer thickness.

It shall be emphasized here that, different from the dual RSD epitaxy process of reference known in the art and as used in 22 nm FDSOI technology or for FinFET manufacturing, the present disclosure does not use a PFET mask, i.e., a PFET-open mask, with a subsequent PFET spacer etch step to separately form the sidewall spacers on the gate stack 250 in the PFET region 200. Instead, a blanket etch is performed without any PFET mask to form the sidewall spacers on both gate structures at the same time. This guarantees that the thickness of the sidewall spacers 160, 260 is substantially identical and further simplifies the process of reference as one mask is saved.

After patterning the sidewall spacers 160, 260, raised source and drain regions 30 are formed as P⁺-doped regions by epitaxially growing a semiconductor layer at the respective locations and using in situ doping with P-type dopants at the desired concentration. Alternatively, the epitaxially grown semiconductor layer may be heavily doped in the regions adjacent to the control gates 150, 250 using ion implantation with dopants of the required type, i.e., P-type dopants. In the illustrated example shown in FIG. 1C, raised source and drain regions for the PFET transistor 200 are formed by in situ doping with P⁺-impurities with the desired dose when epitaxially growing the semiconductor layer 30. In addition to the P⁺-source of the PFET transistor 200, an N⁺-body (not shown) may be formed next to the P⁺-source to function as a body contact to an N-well (not shown) of the substrate 10. Again, ion implantation or in situ doping with appropriate dopants, this time of the opposite type, may be performed according to known techniques.

The present disclosure in particular provides a process wherein a P-type epitaxial layer 30 is grown in both the NFET region 100 and the PFET region 200 without a dedicated mask, in particular without the PFET-open mask used in the process of reference. The portion of the P-type epitaxial layer 30 in the NFET region 100 is used as a sacrificial layer which will be removed in a later step. As a result of the described process, no dedicated PFET-open mask is needed such that the described manufacturing process is simpler than the process of reference.

Due to selective epitaxial growth, the raised source and drain regions 30 may be tapered towards their top such that a small gap between the sidewall spacers 160, 260 and the raised source and drain regions 30 may be formed, as indicated in FIG. 1C.

In the described example, heavily doping and in situ doping with P⁺-impurities may comprise doping with the respective impurities with doping concentrations of N⁺>10²⁰/cm³ to achieve low external resistance. A combination of laser annealing and thermal treatments may be applied to fully activate the dopants and minimize the external resistance. This processing may, in particular, be applied after removal of the below described liner 40 from the structure in FIG. 1G. Furthermore, in situ boron doped (ISBD) SiGe may be epitaxially grown to form the raised source and drain regions of the PFET transistor 200. The present disclosure is, however, not limited to these doping concentrations and/or dopants as the particular formation of the raised source and drain regions described above may be replaced with other techniques known in the art.

In the next step, a liner 40, such as a nitride liner, in particular a thin SiN liner, may be conformally deposited on the structure of FIG. 1C. The liner 40 may be formed with a thickness between 2-5 nm, for instance with a thickness of 3 nm. Subsequently, an NFET mask 45, i.e., a mask with an opening in the NFET region 100, may be formed, as schematically shown in FIG. 1D. As this NFET mask is also required in the process of reference to perform the necessary NFET spacer etch, no additional mask is needed according to the process of the present disclosure.

Different from the process of reference, the NFET mask 45 according to the present disclosure is only used to perform an NFET liner open etch which etches the liner 40 in the NFET region 100. During or after etching the liner 40, the NFET-open mask 45 is stripped, i.e., removed, using known techniques, before continuing with the processing steps related to FIG. 1F. The etch may be performed anisotropically. As a result of the etch, only side parts 140 of the liner 40 on the sides of the sidewall spacers 160 remain that provide the necessary selectivity during the subsequent removal of the P-type sacrificial epitaxial layer 30 in the NFET region 100. The structure after the anisotropic NFET liner open etch is shown in FIG. 1E.

After the liner 40 has been etched back to side parts 140 in the NFET region 100, the P-type sacrificial layer 30 in the NFET region 100 is selectively removed using well-known dry or wet etching techniques, wherein the semiconductor layer 116 acts as an etch-stop layer. In particular, a semiconductor layer 116 formed of Si may act as an etch-stop layer for a selective removal of an epitaxially grown SiGe sacrificial layer in the NFET region 100. By way of example, an etch step using an ammonium hydroxide-hydrogen peroxide mixture (APM), a sulfuric peroxide mixture (SPM) or a similar wet etch may be used. As the remnants of the liner 40 are not removed by this selective etch step, both the sidewall spacers 160 as well as the raised source and drain regions 230 of the PFET region 200 are protected. The resulting structure is shown in FIG. 1F. As the selective etch step to remove the sacrificial layer in the NFET region 100 does not affect the sidewall spacers 160, the thickness of the sidewall spacers 160 remains unchanged and, therefore, substantially identical to the thickness of the sidewall spacers 260. In contrast, the process of reference which uses a dedicated NFET spacer etch step cannot guarantee substantially identical sidewall spacer thicknesses, as two independent etch steps are needed to pattern the sidewall spacers.

After removal of the sacrificial layer on the side of the NFET region 100, and, if necessary, a cleaning step, raised source and drain regions 170 of the NFET transistor 100 are formed. The raised source and drain regions 170 of the NFET transistor 100 may be formed by epitaxially growing a semiconductor layer at the respective locations together with in situ doping or heavily doping the semiconductor layer in the regions adjacent to the control gate 150 using ion implantation with dopants of the required type. In the illustrated example shown in FIG. 1G, raised source and drain regions 170 for the NFET transistor 100 are formed by in situ doping an epitaxially grown semiconductor layer 170 with the desired concentration or implanting N⁺-impurities with the desired dose and power into the epitaxially grown semiconductor layer 170. In particular, in situ phosphorus doped Si may be epitaxially grown with doping concentrations of N⁻>10²⁰/cm³ to form the raised source and drain regions of the NFET transistor 100. The present disclosure is, however, not limited to these doping concentrations and/or dopants as the particular formation of the raised source and drain regions described above may be replaced with other techniques known in the art.

As a result of the above-described process, NFET and PFET transistors 100 and 200 with raised source and drain regions 170 and 230, respectively, are produced which have sidewall spacers with substantially identical thickness.

Remaining parts of the liner 40 may be subsequently removed before or after a wet cap removal of the hard mask layers 158 and 258 (see FIG. 1B) of the gate stacks 150 and 250. Between the tapered raised source and drain regions 170 and 230, respectively, and the corresponding sidewall spacers 160 and 260, lower parts of the liner 140 and 240 (see FIG. 1H) may remain or be removed, depending on whether a full liner etch step is performed.

FIG. 1H shows the final result of the process according to the present disclosure which produces NFET and PFET transistors of a CMOS device which have sidewall spacers 160, 240 with substantially identical thickness without the use of a dedicated PFET-open mask. Compared to the process of reference, one mask is, therefore, saved such that the entire process is simplified, while, at the same time, the established dual raised source and drain epitaxy procedure is maintained.

The above-described manufacturing process may be applied to the highly integrated circuit manufacturing according to the 12 nm FDSOI semiconductor technology where differential spacer approaches do not work due to tighter SRAM pitch (spacer bridging) and the need for junction engineering.

The process is applied to the situation where a P-type epitaxial layer is grown first both in the NFET and PFET regions and later on removed again in the NFET region making use of the selectivity of SiGe versus Si before the N-type epitaxial layer is grown in the NFET region.

After completion of the structure as shown in FIG. 1H, further manufacturing steps may be performed as required and known in the art. In particular, the upper surfaces of the gate electrodes 156 and 256 as well as of the raised source and drain regions 170 and 230 may be silicided to provide appropriate electrical contacts to backend structures. Silicidation may comprise deposition of a metal layer comprising a transition metal, e.g., nickel, titanium or cobalt, on the surfaces of the RSD (raised source and drain) regions and the gate electrodes and performing one or more thermal anneal processes for initiating a chemical reaction between the metal of the metal layer and the semiconductor material of the control gates and the raised source and drain regions. This silicidation process results in the creation of silicided areas wherein remaining residuals of metal material which have not been consumed in the silicidation may be removed in a strip process. The resulting silicided areas provide low-resistance contacts for the backend structures.

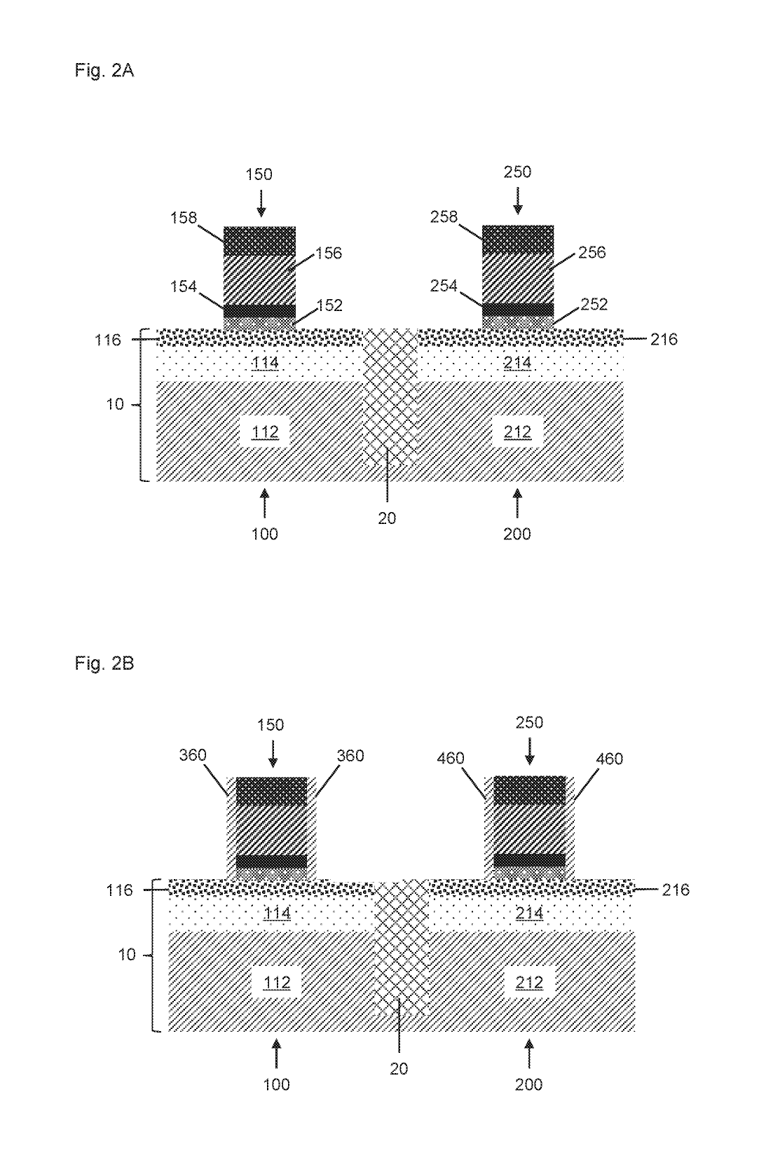

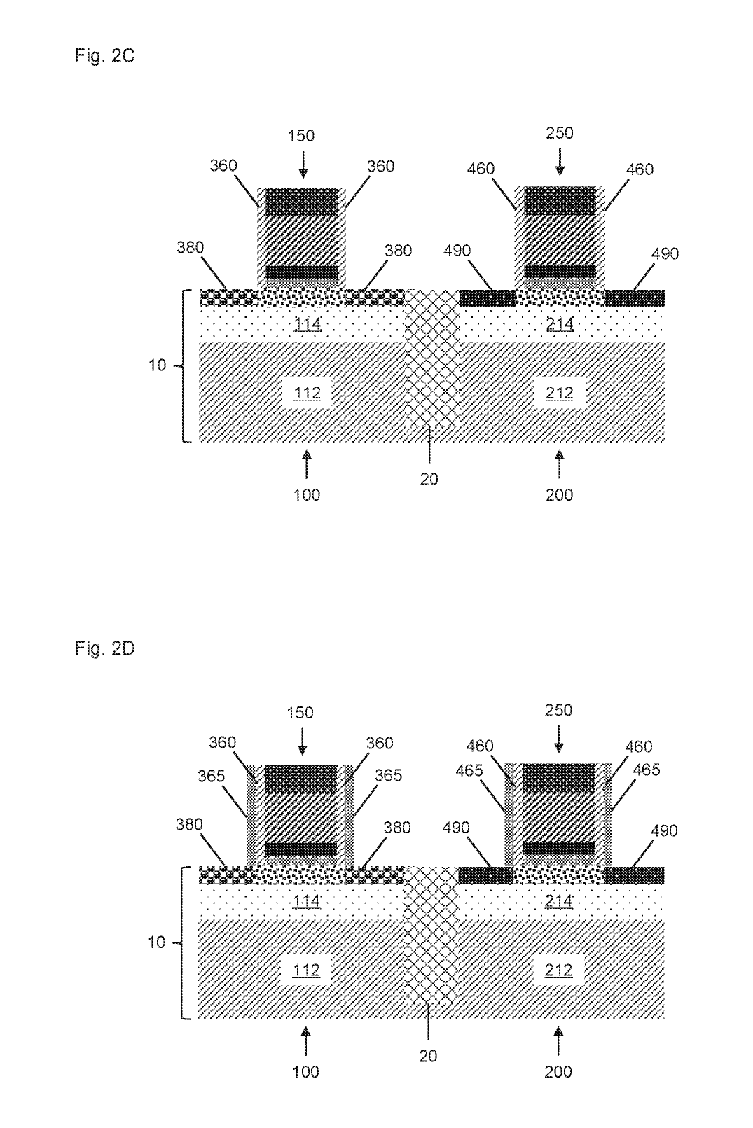

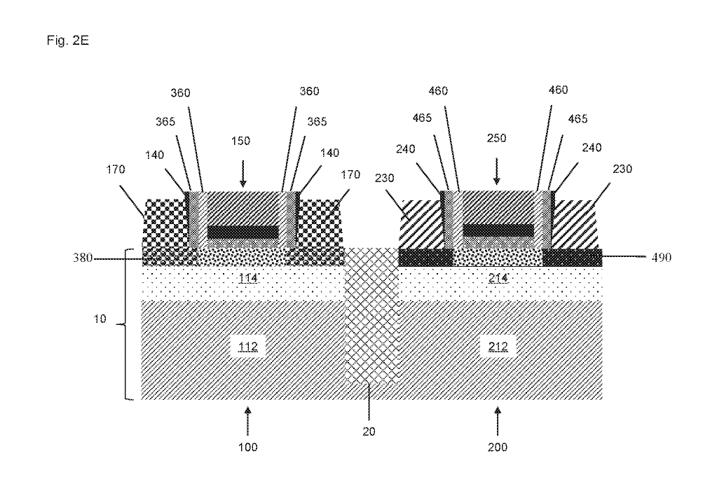

In the following, an extension of the above-described manufacturing process is described with respect to FIGS. 2A-2E. The same reference numbers indicate substantially identical elements to those described above with respect to FIGS. 1A-1H. For the sake of clarity, a repeated description of these elements is omitted in the following. It is, however, understood that the above-described variants and modifications, as well as manufacturing methods, may also be applied to the corresponding elements shown in FIGS. 2A-2E.

FIG. 2A shows the structure of the CMOS device after the gate patterning process. As this structure is substantially identical to the structure shown in FIG. 1A, the corresponding description is not repeated here. It is understood that any of the manufacturing processes and materials described above with respect to FIG. 1A may also be applied to the manufacturing of the structure shown in FIG. 2A.

Similar to the manufacturing process for the sidewall spacers 160, 260 of FIG. 1B as described above, the sidewall spacers 360, 460 shown in FIG. 2B may be manufactured. In particular, the above-described blanket etch is applied to anisotropically etch a conformally deposited spacer layer to form sidewall spacers 360, 460. The same materials may be used for the conformal deposition of the spacer layer. However, for the formation of the sidewall spacers 360, 460, a spacer layer with a lower thickness than the spacer layer described with respect to FIG. 1B is deposited in FIG. 2B. The thickness of the spacer layer 360, 460 may lie in the range of 3-7 nm, and may in particular be 5 nm.

The sidewall spacers 360, 460 shown in FIG. 2B constitute inner sidewall spacers which are used for a self-aligned implantation step to produce extensions, i.e., extremely shallow doped regions with a moderately high dopant concentration, next to the control gates 150, 250. After patterning of the inner sidewall spacers 360, 460, implantation regions (source and drain extensions) 380, 490 are formed substantially aligned with the edges of the inner sidewall spacers 360, 460. The formation of the source and drain extensions 380, 490 as shown in FIG. 2C is carried out in two steps.

In a first step, a PFET-open mask (not shown) is formed over the structure, for instance using a photoresist layer. Subsequently, plasma-assisted doping or shallow implantation with P-type impurities is performed using the control gate 250 as a mask to form source and drain extensions 490 in the semiconductor layer 216 (see FIG. 2B). The source and drain extensions 490 may have a depth or thickness between 10-25 nm. After stripping of the PFET-open mask, an NFET-open mask (not shown) is formed over the structure, for instance using a further photoresist layer. Using the NFET-open mask, plasma-assisted doping or shallow implantation with N-type impurities is performed using the control gate 150 as a mask to form source and drain extensions 380 in the semiconductor layer 116 (see FIG. 2B). Again, a thickness between 10-25 nm may be selected. Any of the impurities known in the art for extension formation may be used in the process according to the present disclosure. The extension regions 380, 490 are lightly doped and a dopant concentration in the range of 10¹⁸/cm³ to 10²²/cm³ may be employed. Subsequently, the NFET-open mask is stripped.

Due to lateral diffusion, extension regions 380, 490 will diffuse under the respective sidewall spacers 360, 460 and overlaps with the corresponding control gates 150 and 250 are formed. The source and drain extensions 380, 490 are part of the junction engineering and help to control short channel effects. In order to assist the control of short channel effects, the sidewall spacers of the illustrative example according to FIGS. 2A-2E are formed in two steps. As described above, thin inner sidewall spacers 360, 460 are formed in a first step. After the formation of the source and drain extensions 380, 490, a second spacer layer may be conformally deposited and etched using a blanket etch to form outer sidewall spacers 365, 465 as shown in FIG. 2D. The second spacer layer may be formed of the same material as the first spacer layer or of a different material. Any of the known spacer materials described above with respect to FIG. 1B may be used. The thickness of the second spacer layer may be between 3-7 nm, and may be in particular 5 nm. The combined thickness of the inner sidewall spacers 360, 460 and the outer sidewall spacers 365, 465 may thus be the same as the thickness of the single-layer sidewall spacers 160, 260 described above with respect to FIG. 1B.

As the outer sidewall spacers 365, 465 are formed after the formation of the source and drain extensions 380, 490, the source and drain extensions exhibit a larger overlap with the control gates 150, 250, therefore, contributing to the control of short channel effects.

After formation of the outer sidewall spacers 365, 465, the manufacturing process for the formation of raised source and drain regions described above with respect to FIGS. 1C-1H may be applied to the structure shown in FIG. 2D. To avoid obscuring the present disclosure, a repeated description of the above-described manufacturing steps and materials is omitted here. It is understood that the same processes and techniques as described above may be applied to the present illustrative example. In particular, a P-type epitaxial layer may be formed without any mask, in particular without a PFET-open mask, to form raised source and drain regions in the NFET region 100 as well as the PFET region 200. After deposition of a liner, in particular an SiN liner, over the structure, an anisotropic etch of the liner is performed in the NFET region only, using an NFET-open mask. Subsequently, the sacrificial part of the P-type epitaxial layer is removed in the NFET region by selectively etching and an N-type epitaxial layer is grown in the NFET region to form raised source and drain regions, as shown in FIG. 2E. Finally, an anisotropic etch of the remaining liner is performed in the PFET region and the hard mask layers 158, 258 (see FIG. 2A) are removed using a wet cap removal. The same variations and modifications as described above with respect to FIGS. 1C-1H may also be applied to the formation of the structure in FIG. 2E.

As shown in FIG. 2E, the resulting structure resembles that of FIG. 1H with the difference that source and drain extensions 380, 490 are provided under the raised source and drain regions 170, 230 and that two-part sidewall spacers are provided instead of single-layer sidewall spacers. Again, a lower part 140 and 240 of the liner may remain or be removed. The structure shown in FIG. 2E exhibits improved control of short channel effects while maintaining substantially identical thicknesses of the sidewall spacers of the NFET transistor 100 and the PFET transistor 200.

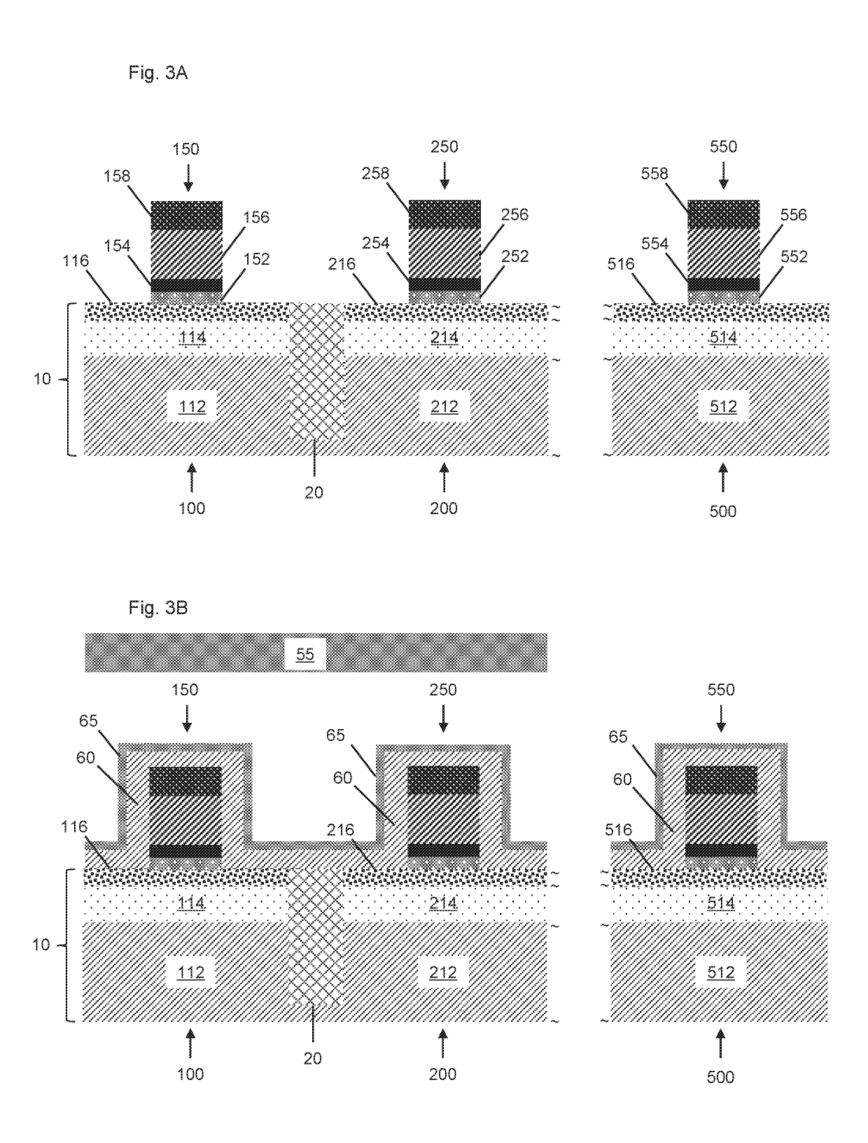

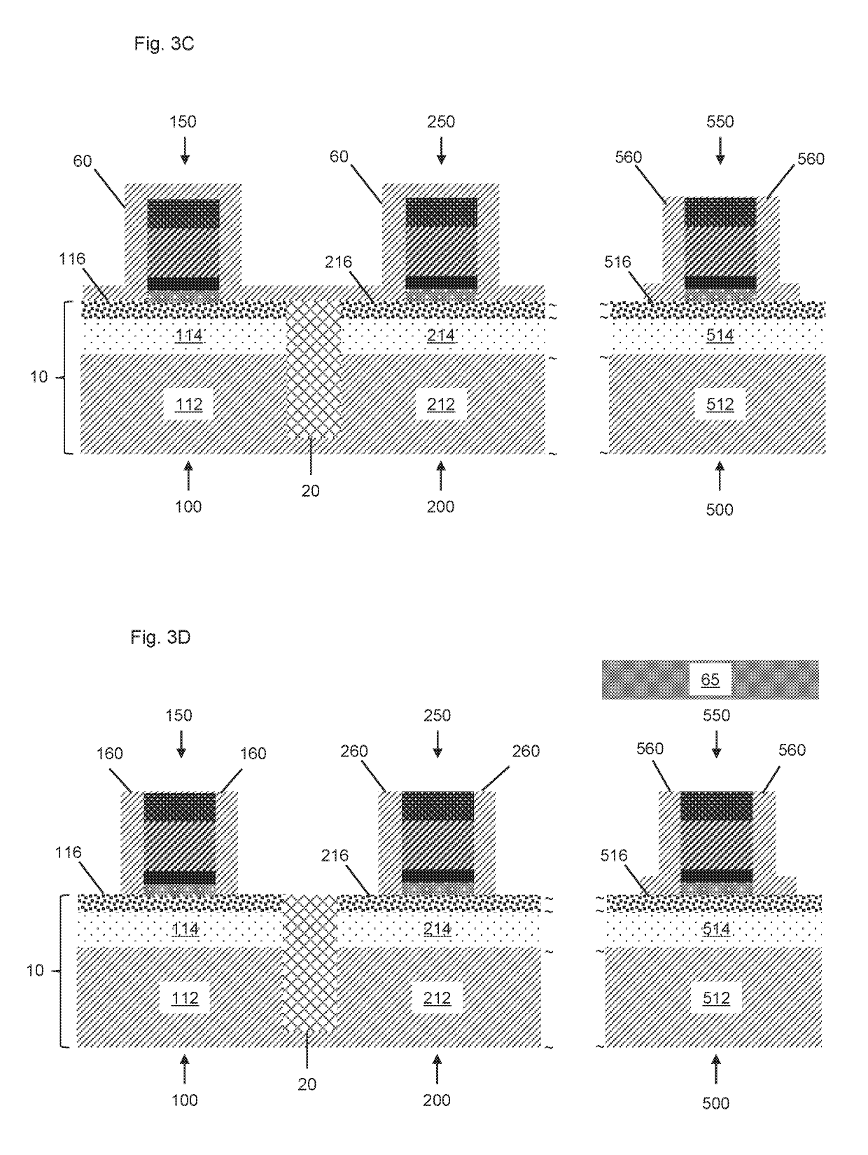

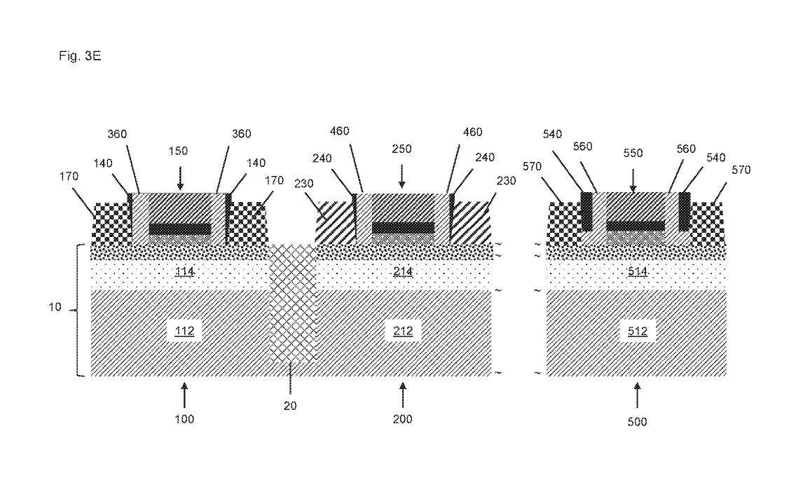

In the following, a further variant of the above-described manufacturing process is described with respect to FIGS. 3A-3E. The same reference numbers indicate identical elements to those described above with respect to FIGS. 1A-1H. For the sake of clarity, a repeated description of these elements is omitted in the following. It is, however, understood that the above-described variants and modifications, as well as manufacturing methods, may also be applied to the corresponding elements shown in FIGS. 3A-3E.

FIG. 3A shows the structure of a CMOS device in combination with I/O device 500 after the gate patterning process. As the structure of the CMOS device comprising the NFET region 100 and the PFET region 200 is identical to the structure shown in FIG. 1A, the corresponding description is not repeated here. It is understood that any of the manufacturing processes and materials described above with respect to FIG. 1A may also be applied to the manufacturing of the structure shown in FIG. 3A.

In addition to the NFET region 100 and PFET region 200, the structure shown in FIG. 3A comprises an I/O device 500 which comprises an input/output (I/O) transistor for connecting the CMOS transistor or any other part of the integrated circuit to a voltage supply. Although shown next to the CMOS transistor in FIG. 3A, the I/O device 500 may be located at a different location in the integrated circuit. In general, the I/O transistor has to support higher bias voltages than the NFET and PFET transistors of the CMOS device and, as a consequence, usually has a fairly long gate length. The relative widths of the gate stacks 150, 250 and 550 shown in FIG. 3A are, therefore, not representative, as the gate stack 550 may in particular be wider than the gate stacks 150 and 250. Also, the illustrative example described with respect to FIGS. 3A-3E uses an NFET transistor for the I/O device 500 to demonstrate the manufacturing process according to the present disclosure. The present disclosure is, however, not limited to an NFET transistor but also includes a corresponding I/O device with a PFET transistor. The below-described manufacturing process may be correspondingly modified to be applicable to a PMOS-type I/O device.

According to the illustrative example shown in FIG. 3A, the gate stack 550 of the I/O device 500 comprises an insulating layer 552, an HKMG layer 554, a gate electrode layer 556 and a hard mask 558 provided on top of each other and on the semiconductor layer 516. Here, the SOI structure comprising a semiconductor layer 516 on a BOX layer 514, which itself is provided on a semiconductor bulk substrate 512, may be formed from the same substrate used for the SOI structures in the NFET region 100 and the PFET region 200. Consequently, layer thicknesses and materials may be identical to those of the SOI structures in the NFET and PFET regions. Likewise, the layers of the gate stack 550 of the I/O device 500 may be formed from the same layers used for the gate stacks 150 and 250 of the NFET and PFET transistors. Consequently, layer thicknesses and materials of the layers of the gate stack 550 may be identical to those of the layers forming the gate stacks 150 and 250. In this case, the gate stacks 150, 250 and 550 may be patterned at the same time in a single etch step using the hard mask 158, 258 and 558. The present disclosure is, however, not limited to this example. As a consequence, the gate stack 550 may be separately patterned and may in particular comprise layers which differ from the layers of the gate stacks 150 and 250 in their composition and thickness. Any of the gate structures known in the art for I/O transistors, in particular the layers and materials described above with respect to FIG. 1A, may be used for the gate stack 550 of the I/O device 500. In particular, a thicker gate insulating layer 552 may be used for the I/O device 500 than for the NFET and PFET transistor, as the I/O device is made for higher voltages. In addition, even the structure and composition of the SOI substrate underlying the gate stack 550 may differ from the SOI substrates underlying the gate stacks 150 and 250. For the sake of simplicity, identical structures of the SOI substrates and the gate stacks are shown in the FIGS. 3A-3E.

After patterning the gate structures 150, 250 and 550, a spacer layer 60, for instance including or consisting of silicon oxide, silicon nitride and/or state-of-the-art low-k materials, may be formed over the fully etched gate structures 150, 250 and 550, e.g., through a conformal deposition process such as LP-CVD or MLD, as shown in FIG. 3B. In one particular example, an SiBCN layer may be formed over the gate structures. Also, a multilayer may be formed over the gate structures by subsequently growing or depositing respective layers. The spacer layer 60 may be formed with a thickness in a range of 5-15 nm, in particular in a range of 8-12 nm. After deposition of the spacer layer 60, a liner 65, in particular an oxide liner, may be deposited on the spacer layer 60, e.g., through a conformal deposition process, i.e., a process that is capable of depositing a film that follows the contour of the structure shown in FIG. 3B. Specifically, LP-CVD, MLD, evaporation or chemical solution deposition may be employed in forming the oxide liner 65 on the spacer layer 60. In particular, SiO₂ may be used for the liner 65. The oxide liner 65 may be formed with a thickness in a range of 3-7 nm, in particular with a thickness of 5 nm.

Different from the process of reference for the formation of sidewall spacers for an I/O transistor, the manufacturing process according to the present disclosure does not require the deposition of an additional silicon nitride spacer layer on the oxide liner 65. Instead, an I/O-open mask 55 is formed over the NFET region 100 and the PFET region 200 with an opening in the region of the I/O device 500 for further processing of the I/O device. The corresponding structure is shown in FIG. 3B. The I/O-open mask 55 may be formed according to any of the processes known in the art. In particular, a photoresist mask may be used for the I/O-open mask 55.

With the I/O-open mask 55 in place, one or more etch steps are performed to etch through the horizontal parts of the liner 65 and the spacer layer 60 in the region of the I/O device 500. By way of example, wet etching or dry etching may be used. As the vertical parts of the liner 65 on the sides of the gate stack 550 in the I/O region 500 are not affected by these etch steps, the remaining sidewall spacers 560 in the I/O region 500 have an L-shape as shown in FIG. 3C.

Subsequent to the spacer etch in the I/O region 500, the I/O-open mask 55 is stripped and the remaining parts of the liner 65, in particular in the NFET region 100 and the PFET region 200, as well as the vertical parts in the I/O region 500, are stripped using appropriate etching. As a result, a structure with L-shaped, i.e., thick, sidewall spacers 560 on the sides of the gate structure 550 of the I/O device 500 and a conformal spacer layer 60 in the NFET region 100 and the PFET region 200 are formed, as shown in FIG. 3C. Due to their L-shape, the sidewall spacers 560 of the I/O device are thicker at the base of the gate stack 550, thereby forming a thick spacer to reduce inter-gate spacing and parasitic capacitance of the I/O device. Outside the base, the sidewall spacers 560 are, however, formed with a substantially identical thickness to the sidewall spacers 160 and 260 of the NFET and PFET transistors, as shown in FIG. 3D.

Different from the process of reference, which uses a PFET-open mask and an NFET-open mask to subsequently etch the sidewall spacers of the corresponding gate stacks and epitaxially grow the raised source and drain regions, the manufacturing process according to the present disclosure uses an I/O block mask 65 to block further etching of the sidewall spacers 560 of the I/O device, as shown in FIG. 3D. The sidewall spacers 160, 260 of the NFET and PFET transistors are then formed through a single blanket etch step as described above with respect to FIG. 1B with the I/O block mask 65 in place. Subsequently, the I/O block mask 65 is stripped and identical processing steps as described above with respect to FIGS. 1C-1H are performed to deposit a P-type epitaxial layer, forming raised source and drain regions in the NFET region 100, the PFET region 200 and the I/O region 500, to form a conformal liner over the entire structure, to provide a PFET-block mask, which blocks processing of the PFET region 200, to etch into the liner in the NFET region and the I/O region, to strip the PFET-block mask, and to selectively etch away the sacrificial part of the P-type epitaxial layer in the NFET region and the I/O region. The only difference with respect to the processing steps of FIGS. 1C-1H is that a PFET-block mask, which blocks processing in the PFET region 200 only, is used according to the present illustrative example instead of an NFET-open mask, which, as shown in FIG. 1D, has an opening in the NFET region only.

Finally, the raised source and drain regions 170 and 570 of the NFET transistor 100 and the I/O transistor 500 are formed in the same way as forming the raised source and drain regions 170 shown in FIG. 1G by epitaxially growing an appropriate N-type layer in the appropriate locations. As described with respect to FIG. 1G, in situ doping may be used to form phosphorus doped Si source and drain regions with doping concentrations of N⁻>10²⁰/cm³ as the raised source and drain regions of the NFET transistor 100 and the I/O device 500. The present disclosure is, however, not limited to these doping concentrations and/or dopants as the particular formation of the raised source and drain regions described above may be replaced with other techniques known in the art.

As a result of the above-described process, NFET, PFET and I/O transistors 100, 200 and 500 with raised source and drain regions 170, 230 and 570 are produced wherein the NFET and PFET transistors have sidewall spacers with substantially identical thickness. As shown in FIG. 3E, remaining parts of the liner may be present between the tapered raised source and drain regions 170 and 230, respectively, and the corresponding sidewall spacers 360 and 460 as lower parts of the liner 140 and 240. Also, lower parts 540 of the liner may remain on the L-shaped sidewall spacers 560, as shown in FIG. 3E, to form thick spacers on the gate stack of the I/O device 500. Alternatively, these remaining parts may be removed in a further liner etch step.

FIG. 3E shows the final structure including the CMOS device with NFET transistor 100 and PFET transistor 200 and the I/O device after a wet cap removal of the hard mask layers 158, 258 and 558 of the gate stacks 150, 250 and 550.

As mentioned above, a corresponding structure with respect to FIG. 3E, wherein the I/O device 500 is formed as a PMOS device, may be manufactured by appropriately modifying the above-described manufacturing process. In this case, the P-type epitaxial semiconductor layer may be selectively etched away only in the NFET region 100 while the raised source and drain regions 570 in the I/O region 500 remain. The processing is, therefore, adapted by using an NFET-open mask instead of a PFET-block mask to remove the liner only in the NFET region such that the deposited raised source and drain regions in the I/O region remain unaffected by the selective etching of the sacrificial layer.

Compared to the process of reference, no silicon nitride liner is deposited to form thick spacers for the I/O device, which would have to be removed in an isotropic removal step with an I/O block mask. Also, as described above with respect to FIGS. 1A-1H, one less mask is necessary according to the process of the present disclosure as compared to the process of reference.

Consequently, the above-described process of forming raised source and drain regions and sidewall spacers of substantially identical thickness using a sacrificial layer is compatible with processes for thick spacer module formation for I/O transistors. Only one additional oxide liner is needed while a conformal SiN liner and a mask are saved, such that the overall process is simplified.

The above-described manufacturing processes, therefore, provide methods for manufacturing CMOS devices with substantially identical spacer thickness, even in combination with I/O devices. Junction engineering and control of short channel effects using extensions are easily implemented in the described manufacturing processes. No differential spacer approaches are needed anymore such that the described manufacturing processes may be applied to the highly integrated circuit manufacturing according to the 12 nm FDSOI semiconductor technology.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a short-hand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method of manufacturing a complementary metal-oxide-semiconductor (CMOS) device comprising an N-type metal-oxide-semiconductor (NMOS) region and a P-type metal-oxide-semiconductor (PMOS) region, comprising:
depositing a raised source and drain (RSD) layer of a first type in said NMOS region and said PMOS region at a same time;
selectively removing said RSD layer of said first type from one of said NMOS region and said PMOS region; and
depositing an RSD layer of a second type in the other of said one of said NMOS region and said PMOS region.

2. The method of claim 1, further comprising:
forming and patterning at least one gate stack in each of said NMOS region and said PMOS region on a substrate;
conformally depositing a spacer layer over said at least one gate stack and said substrate; and
etching said spacer layer in said NMOS region and said PMOS region at a same time to form sidewall spacers of said at least one gate stack in each of said NMOS region and said PMOS region.

3. The method of claim 1, wherein said RSD layer of said first type is a P-type semiconductor layer and said RSD layer of said second type is an N-type semiconductor layer; and wherein said RSD layer of said first type is removed in said NMOS region and said RSD layer of said second type is deposited in said NMOS region.

4. The method of claim 3, wherein said RSD layer of said first type comprises in situ boron doped SiGe and wherein said RSD layer of said second type comprises in situ phosphorus doped Si.

5. The method of claim 2, wherein selectively removing said RSD layer of said first type comprises:
conformally depositing a nitride liner;
providing a mask covering the other of said NMOS region and said PMOS region; and
etching through said liner in said one of said NMOS region and said PMOS region.

6. The method of claim 5, wherein selectively removing said RSD layer of said first type further comprises:
stripping said mask covering said other of said NMOS region and said PMOS region; and
selectively etching said RSD layer of said first type in said one of said NMOS region and said PMOS region.

7. The method of claim 6, wherein said substrate comprises a silicon-on-insulator (SOI) structure with a semiconductor layer on a buried oxide layer, and wherein said semiconductor layer acts as an etch-stop layer for said selectively etching of said RSD layer of said first type.

8. The method of claim 1, wherein forming and patterning said at least one gate stack in each of said NMOS region and said PMOS region comprises:
forming a high-k metal gate (HKMG) layer stack on said substrate;
forming and patterning a hard mask layer on said HKMG layer stack; and
etching through said HKMG layer stack using said hard mask layer.

9. The method of claim 1, wherein said spacer layer is deposited with a thickness in a range of 8-12 nm.

10. The method of claim 1, wherein said spacer layer comprises SiBCN.

11. The method of claim 2, wherein said RSD layer of said first type is epitaxially grown.

12. The method of claim 1, wherein etching said spacer layer in said NMOS region and said PMOS region at said same time to form sidewall spacers of said at least one gate stack comprises:
etching said spacer layer to form inner sidewall spacers of said at least one gate stack;
forming source and drain extensions in said substrate next to said inner sidewall spacers;
conformally depositing a second spacer layer over said at least one gate stack, said inner sidewall spacers and said substrate in said NMOS region and said PMOS region; and
etching said second spacer layer in said NMOS region and said PMOS region at a same time to form outer sidewall spacers of said at least one gate stack.

13. The method of claim 12, wherein forming source and drain extensions in said substrate comprises:
providing a PMOS-open mask that covers said NMOS region;
performing one of plasma-assisted doping and shallow implantation with P-type impurities to form source and drain extensions in said substrate in said PMOS region;
stripping said PMOS-open mask;
providing an NMOS-open mask that covers said PMOS region;
performing one of plasma-assisted doping and shallow implantation with N-type impurities to form source and drain extensions in said substrate in said NMOS region; and
stripping said NMOS-open mask.

14. The method of claim 12, wherein at least one of a thickness of said inner spacer layer is in a range of 3-7 nm and a thickness of said second spacer layer is in a range of 3-7 nm.

15. The method of claim 1, further comprising:
forming and patterning at least one gate stack in an I/O region on said substrate before conformally depositing said spacer layer;
wherein said spacer layer is deposited over said at least one gate stack in said NMOS region, said PMOS region and said I/O region and said substrate.

16. The method of claim 15, further comprising forming L-shaped I/O spacers in said I/O region before etching said spacer layer in said NMOS region and said PMOS region.

17. The method of claim 16, wherein forming said L-shaped I/O spacers comprises:
conformally depositing an oxide liner over said spacer layer;
providing an I/O-open mask covering said NMOS region and said PMOS region;
etching into said oxide liner and said spacer layer in said I/O region to form said L-shaped I/O spacers; and
stripping said I/O-open mask.

18. The method of claim 17, further comprising stripping said oxide liner and providing an I/O-closed mask covering said I/O region before etching said spacer layer in said NMOS region and said PMOS region.

19. The method of claim 15, wherein an RSD layer of a first type is deposited in said NMOS region, said PMOS region and said I/O region at a same time, wherein said RSD layer of said first type is selectively removed in one of said NMOS region and said PMOS region and in said I/O region, and wherein an RSD layer of a second type is deposited in said one of said NMOS region and said PMOS region and in said I/O region.

20. A complementary metal-oxide-semiconductor (CMOS) device comprising:
an N-type metal-oxide-semiconductor (NMOS) transistor with a first sidewall spacer; and
a P-type metal-oxide-semiconductor (PMOS) transistor with a second sidewall spacer, wherein said first and second sidewall spacers are made from a same layer of spacer material and wherein a thickness of said first sidewall spacer is substantially identical to a thickness of said second sidewall spacer.
